(19) United States
(12) Patent Application Publication
(10) Pub. No.: US 2025/0261516 A1
(43) Pub. Date: Aug. 14, 2025

(54) DISPLAY DEVICE

(71) Applicant: LG Display Co., Ltd., Seoul (KR)

(72) Inventor: Hojin RYU, Paju-si (KR)

(73) Assignee: LG Display Co., Ltd., Seoul (KR)

(21) Appl. No.: 18/920,166

(22) Filed: Oct. 18, 2024

(30) Foreign Application Priority Data
Feb. 14, 2024 (KR) 10-2024-0021109

(51) Int. Cl. H10K 59/122; H10K 59/80; H10K 102/00

(52) U.S. Cl. CPC H10K 59/122; H10K 59/87; H10K 2102/351

(57) ABSTRACT

A display device according to one example includes a substrate including a display area including a plurality of pixels, and a non-display area surrounding the display area, a protruding pattern disposed on the substrate and located at a boundary of adjacent pixels, an anode electrode disposed on each of the pixels on the substrate, a bank disposed on the anode electrode and exposing the protruding pattern, and an organic layer disposed on the anode electrode and the bank, in which the organic layer is separated at the boundary of the pixels.

### CROSS REFERENCE TO RELATED APPLICATION

The present application claims priority to Korean Patent Application No. 10-2024-0021109, filed Feb. 14, 2024.

### BACKGROUND

### Technical Field

The present specification relates to a display device, and more specifically, to a display device in which a lateral leakage current generated at the boundary of adjacent pixels can be prevented.

### Discussion of the Related Art

As the information society develops, various demands for display devices for displaying images are increasing, and various types of display devices such as liquid crystal display (LCD) devices and organic light emitting diode (OLED) display devices are utilized.

Among the display devices, there is an advantage in that the OLED display device as the self-luminous type has a wider viewing angle, a higher contrast ratio, is lighter, thinner, and has lower consumed power than the LCD because it does not require a separate backlight. In addition, the OLED display device has the advantages of being capable of DC low voltage driving, having a fast response time, and especially having inexpensive manufacturing costs.

Recently, there is a trend to increase the resolution of the OLED display device for clearer image quality.

### SUMMARY

Accordingly, embodiments of the present disclosure are directed to a display device that substantially obviates one or more of the problems due to limitations and disadvantages of the related art.

An aspect of the present disclosure is to provide a display device in which a lateral leakage current between adjacent pixels can be minimized.

Another aspect of the present disclosure is to provide a display device in which an organic layer may be easily separated/be made discontinuous through a protruding pattern located at the boundary between pixels and a protrusion of a first passivation layer.

Another aspect of the present disclosure is to provide a display device in which an organic layer may be easily separated/made discontinuous by removing a bank, a planarization layer, etc. from the boundary between pixels to expose a protruding pattern.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a display area including a plurality of pixels, and a non-display area surrounding the display area, a protruding pattern disposed on the substrate and located at a boundary of adjacent pixels, an anode electrode disposed on each of the pixels on the substrate, a bank disposed on the anode electrode and exposing the protruding pattern, and an organic layer disposed on the bank, wherein the organic layer is separated (discontinuous) at the boundary of the pixels.

In another aspect, a display device comprises a substrate including a display area including a plurality of pixels, and a pad area near the display area, a first conductive layer including a data line and a light blocking layer on the substrate, a semiconductor layer overlapping the light blocking layer on the first conductive layer, a gate insulating layer on the semiconductor layer, a second conductive layer including a first pad electrode disposed in the pad region on the gate insulating layer, a gate electrode overlapping a channel area of the semiconductor layer, a source electrode connected to a source area of the semiconductor layer, and a drain electrode connected to a drain area of the semiconductor layer, a first passivation layer disposed on the second conductive layer, and a third conductive layer disposed on the first passivation layer and including a second pad electrode disposed on the first pad electrode in the pad area and a protruding pattern located at a boundary of the pixels.

The display device according to the examples may include the protruding pattern located at the boundary between adjacent pixels. The protruding pattern may be formed together when the second pad electrode, etc. are formed and may have a greater width than the protrusion of the first passivation layer formed using the protruding pattern as the mask. The organic layer of the organic light emitting element of the display device is integrally deposited on the entirety of the pixels, and the organic layer may be separated/discontinuous at the boundary between adjacent pixels due to steps formed by the above-described protrusion and protruding pattern/layer. Therefore, it is possible to minimize the lateral leakage current leaking between the adjacent pixels.

The method of manufacturing a display device according to the examples herein described may expose the protruding pattern by removing the second passivation layer, the planarization layer, and the bank that are disposed on the protruding pattern at the boundary between the adjacent pixels. Therefore, by easily separating the organic layer at the boundary between the adjacent pixels by the exposed protruding pattern, it is possible to prevent the lateral leakage current.

In the display device according to the examples, it is possible to prevent the lateral leakage current leaking between the adjacent pixels, thereby increasing the color gamut and prevent display quality defects, thereby increasing the lifetime of the display device.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view of a display device according to a first example.

FIG. 2 is a cross-sectional view of the display device according to the first example.

FIG. 3 is an enlarged cross-sectional view of area Q1 in FIG. 2.

FIG. 4 is a cross-sectional view of a display device according to a second example.

FIG. 5 is an enlarged cross-sectional view of area Q2 in FIG. 4.

FIG. 6 is an enlarged cross-sectional view of area Q3 in FIG. 5.

FIGS. 7 to 17 are cross-sectional views for each process showing a method of manufacturing a display device according to a second example.

### DETAILED DESCRIPTION

Hereinafter, examples will be described with reference to the accompanying drawings. In the specification, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the examples. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

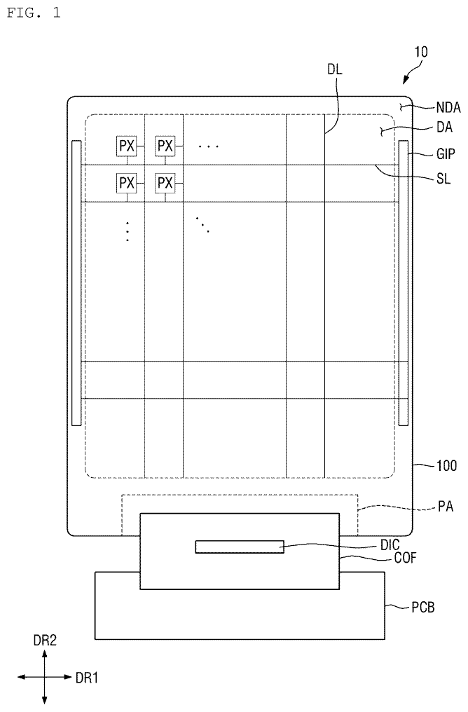

FIG. 1 is a plan view of a display device according to a first example.

Referring to FIG. 1, a display device 10 according to the first example may be an organic light emitting diode display device, but is not limited thereto and may be a liquid crystal display device or an inorganic light emitting display device. The following description will focus on a case in which the display device according to the first example is an organic light emitting diode display device. The organic light emitting diode display device may include a display panel 100. The display panel 100 may include a display area DA and a non-display area NDA located near the display area DA. That is, the display area DA and the non-display area NDA located near the display area DA can be defined in the display panel 100. All areas to be described below can be described as being included in the display panel 100 and described as being defined in the display panel 100.

The display area DA may include a plurality of pixels PX. The plurality of pixels PX may be arranged in a matrix arrangement manner, but are not limited thereto. The plurality of pixels PX may each be connected to a gate line SL and a data line DL. The gate line SL may extend in a first direction DR1, and the data line DL may extend in a second direction DR2. The display area DA may have a rectangular shape including short sides extending in a first direction DR1 and long sides extending in a second direction DR2, but is not limited thereto.

The non-display area NDA may surround the display area DA in a plan view. For example, the non-display area NDA may be disposed to surround all of long sides (or sides extending in the second direction DR2) and short sides (or sides extending in the first direction DR1) of the display area DA, but is not limited thereto.

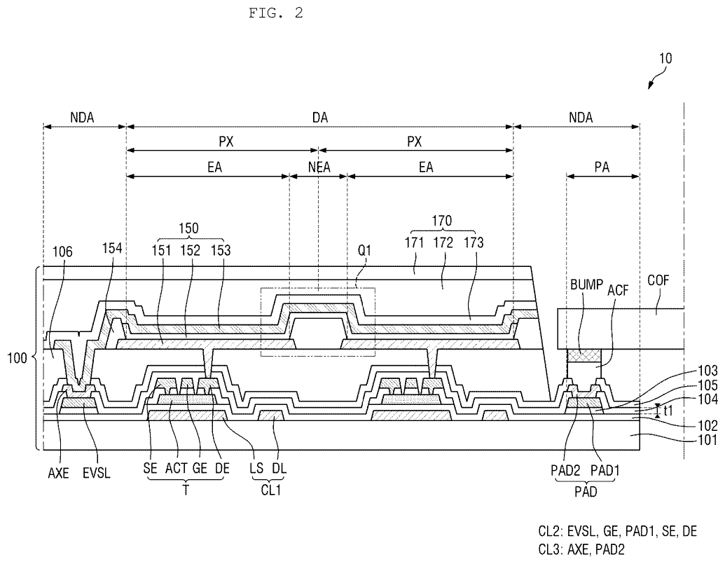

A gate driver GIP may be disposed in the non-display area NDA at one side and the other side of the display area DA in the first direction DR1. The gate driver GIP may be formed in the form of an integrated circuit on the substrate 101 (see FIG. 2) of the display panel 100, but is not limited thereto and may be formed in the form of a driving chip. FIG. 1 shows that the gate driver GIP is disposed at each of the left and right sides of the display area DA, but is not limited thereto, and the gate driver GIP may be disposed only at any one of the left and right sides. The gate lines SL may each extend from the gate driver GIP.

The non-display area NDA may include a pad area PA. The pad area PA may be disposed at an end portion of the other side of the non-display area NDA in the second direction DR2.

A printed circuit film COF may be attached on the pad area PA. A driving chip DIC may be mounted on the printed circuit film COF. Although FIG. 1 shows that only one printed circuit film COF is disposed, the present specification is not limited thereto, and a plurality of printed circuit films COF may be present. The printed circuit film COF may have one end connected to the pad area PA and the other end connected to a printed circuit board PCB.

FIG. 2 is a cross-sectional view of the display device according to the first example. FIG. 2 shows a cross-sectional structure of the display device according to FIG. 1 cut in the second direction DR2. Since FIG. 2 shows only two pixels PX of the display area DA, an area ratio between the display area DA and the non-display area NDA of FIG. 1 may differ from an area ratio between the display area DA and the non-display area NDA of FIG. 2. FIG. 2 shows two adjacent pixels PX, and each pixel PX may include an emission area EA and a non-emission area NEA near the emission area EA. The emission area EA may be disposed in each pixel PX and may be a central portion of an anode electrode 151 of each pixel PX. For example, the emission area EA may indicate an area exposed by a bank 154 of the anode electrode 151. On the other hand, the non-emission area NEA may indicate an area of the pixel PX that is not the emission area EA. The bank 154 may be disposed in the non-emission area NEA of the display panel 100 according to FIG. 2. That is, an area in which the bank 154 is disposed can be defined as the non-emission area NEA.

Referring to FIGS. 1 and 2, the display panel 100 may include a substrate 101, a first conductive layer CL1, a buffer layer 102, a semiconductor layer ACT, a gate insulating layer 103, a second conductive layer CL2, a first passivation layer 104, a third conductive layer CL3, a second passivation layer 105, a planarization layer 106, a light emitting element 150, and an encapsulation layer 170.

The substrate 101 may include one or more plastic materials. For example, the substrate 101 may be a multi-substrate including a plurality of plastic materials such as polyimide, but is not limited thereto. The substrate 101 may be a rigid substrate made of glass, quartz, etc.

The first conductive layer CL1 may be disposed on the substrate 101. The first conductive layer CL1 may be formed of a single layer or multiple layers made of any one of molybdenum (Mo), aluminum (Al), chromium (Cr), nickel (Ni), neodymium (Nd), and copper (Cu) or an alloy thereof, but is not limited thereto. The first conductive layer CL1 may include a light blocking layer LS and a data line DL.

The buffer layer 102 may be formed on the first conductive layer CL1. The buffer layer 102 can minimize or delay the diffusion of moisture or oxygen permeating the substrate 101. The buffer layer 102 may be formed by alternately stacking silicon nitride (SiNₓ) and silicon oxide (SiOₓ) at least once.

The semiconductor layer ACT may be disposed on the buffer layer 102. The semiconductor layer ACT may include a metal oxide semiconductor such as indium-gallium-zinc oxide (IGZO) and a silicon-based semiconductor material such as amorphous silicon or polycrystalline silicon, but is not limited thereto. The semiconductor layer ACT may include a channel area, a source area, and a drain area. The semiconductor layer ACT may overlap the light blocking layer LS.

Since the polycrystalline semiconductor layer has higher mobility than the amorphous semiconductor layer and the oxide semiconductor layer, consumed power can be low, and reliability can be excellent. Therefore, the driving transistor may be formed of the polycrystalline semiconductor layer.

The gate insulating layer 103 may be disposed on the semiconductor layer ACT. The gate insulating layer 103 can prevent a short between the semiconductor layer ACT and the gate electrode GE of the second conductive layer CL2 disposed on the semiconductor layer ACT. The gate insulating layer 103 may be made of the same material as the buffer layer 102, but is not limited thereto. For example, the gate insulating layer 103 may be made of an inorganic material such as silicon nitride (SiNₓ) or silicon oxide (SiOₓ), but is not limited thereto.

FIG. 2 shows that the gate insulating layer 103 is disposed in only an area overlapping a low potential power line EVSL, gate electrode GE, source electrode SE, drain electrode DE, and first pad electrode PAD1 of the second conductive layer CL2. However, the present specification is not limited thereto, and the gate insulating layer 103 may be formed throughout the display area DA and the non-display area NDA.

The second conductive layer CL2 may be disposed on the gate insulating layer 103. The second conductive layer CL2 may include the low potential power line EVSL, the gate electrode GE, the source electrode SE, the drain electrode DE, and the first pad electrode PAD1.

The low potential power line EVSL may be disposed in the non-display area NDA. The low potential power line EVSL is shown as being disposed in the non-display area NDA located at an opposite side of the pad area PA with the display area DA interposed therebetween, but is not limited thereto.

The gate electrode GE may overlap the channel area of the semiconductor layer ACT. The source electrode SE may be connected to the source area of the semiconductor layer ACT, and the drain electrode DE may be connected to the drain area of the semiconductor layer ACT. The semiconductor layer ACT, the gate electrode GE, the drain electrode DE, and the source electrode SE may form a thin film transistor T. Although FIG. 2 shows that the gate electrode GE, the drain electrode DE, and the source electrode SE are located coplanarly, but the present specification is not limited thereto. For example, the drain electrode DE and the source electrode SE may be disposed on the third conductive layer CL3, and the gate electrode GE may be disposed on the second conductive layer CL2.

The first pad electrode PAD1 may be disposed on the pad area PA. The first pad electrode PAD1 may be connected to the data line DL, the low potential power line EVSL, or the high potential power line, but is not limited thereto.

The second conductive layer CL2 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, but is not limited thereto.

The gate electrode GE may be disposed together with the gate line SL.

The first passivation layer 104 may be disposed on the second conductive layer CL2. The first passivation layer 104 may include at least one of the exemplified materials of the gate insulating layer 103, but is not limited thereto. The first passivation layer 104 may be formed throughout the display area DA and the non-display area NDA. The first passivation layer 104 may have a uniform thickness t1 for each area.

The third conductive layer CL3 may be disposed on the first passivation layer 104. The third conductive layer CL3 may include an auxiliary electrode AXE and a second pad electrode PAD2. The auxiliary electrode AXE may be disposed in the non-display area NDA and may overlap the low potential power line EVSL. The second pad electrode PAD2 may be disposed in the pad area PA and may overlap the first pad electrode PAD1. A portion of the first passivation layer 104 may expose an upper surface of the low potential power line EVSL and an upper surface of the first pad electrode PAD1. The auxiliary electrode AXE and the second pad electrode PAD2 may be in direct contact with the upper surface of the low potential power line EVSL and the upper surface of the first pad electrode PAD1 that are partially exposed. The first pad electrode PAD1 and the second pad electrode PAD2 may form a pad electrode PAD. Although FIG. 2 shows that the pad electrode PAD is formed of a double layer of the first pad electrode PAD1 and the second pad electrode PAD2, the present specification is not limited thereto. The third conductive layer CL3 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but is not limited thereto.

The second passivation layer 105 may be disposed on the third conductive layer CL3. The second passivation layer 105 may include at least one of the exemplified materials of the gate insulating layer 103, but is not limited thereto. The second passivation layer 105 may be disposed in the display area DA and the non-display area NDA. The second passivation layer 105 may partially expose the upper surfaces of the auxiliary electrode AXE and the second pad electrode PAD2.

The planarization layer 106 may be disposed on the second passivation layer 105. The planarization layer 106 may planarize an upper portion of the thin film transistor T and protect the thin film transistor T. The planarization layer 106 may be made of an organic material. For example, the planarization layer 106 may be made of an organic material including an acrylic resin, an epoxy resin, a phenolic resin, a polyamide resin, or a polyimide resin, but is not limited thereto. The planarization layer 106 may expose the auxiliary electrode AXE and the pad area PA.

The printed circuit film COF may be attached to the pad area PA. A bump BUMP may be disposed on a lower surface of the printed circuit film COF. An anisotropic conductive film ACF may be disposed between the bump BUMP and the pad electrode PAD. The anisotropic conductive film ACF may include a resin and conductive balls dispersed in the resin. The bump BUMP and the pad electrode PAD may be electrically connected through the conductive balls.

The anode electrode 151 may be disposed on the planarization layer 106. The anode electrode 151 may be electrically connected to the drain electrode DE of the thin film transistor T through the contact hole formed in the planarization layer 106, the second passivation layer 105, and the first passivation layer 104. The anode electrode 151 may be a reflective electrode that reflects light, but is not limited thereto. The anode electrode 151 may include a metal material with high reflectivity, such as a laminated structure (Ti/Al/Ti) of aluminum (Al) and titanium (Ti), a laminated structure (ITO/AI/ITO) of aluminum (Al) and indium tin oxide (ITO), or an APC alloy, and may be formed of a single layer or multiple layers, but is not limited thereto.

The organic layer 152 may be disposed on the anode electrode 151. The organic layer 152 may include a first stack, a second stack, and a first charge generation layer that are provided on the anode electrode 151. The first stack may be provided on the anode electrode 151 and configured in a structure in which a hole injecting layer (HIL), a hole transporting layer (HTL), a blue (B) emitting layer (EML1), and an electron transporting layer (ETL) are sequentially stacked, but is not limited thereto.

The first charge generation layer serves to supply charges to the first stack and the second stack. The first charge generation layer may include an N-type charge generation layer for supplying electrons to the first stack and a P-type charge generation layer for supplying holes to the second stack. The N-type charge generation layer may include a metal material as a dopant.

The second stack may be provided on the first stack and configured in a structure in which the hole transporting layer (HTL), a yellow green (YG) emitting layer (EML2), the electron transporting layer (ETL), and the electron injecting layer (EIL) are stacked sequentially.

As a result, the organic layer 152 may be provided as a common layer throughout adjacent pixels PX as shown in FIG. 2. For example, the organic layer 152 may be a white organic layer that emits light of white, but is not limited thereto and may be one of a red organic layer, a green organic layer, and a blue organic layer.

In some examples, the organic layer 152 may include the first stack, the second stack, the third stack, the first charge generation layer between the first stack and the second stack, and a second charge generation layer between the second stack and the third stack that are provided on the anode electrode 151.

The first stack may be provided on the anode electrode 151 and configured in a structure in which the hole injecting layer (HIL), the hole transporting layer (HTL), a blue (B) emitting layer (EML1), and the electron transporting layer (ETL) may be stacked sequentially.

The first charge generation layer serves to supply charges to the first stack and the second stack. The first charge generation layer may include an N-type charge generation layer for supplying electrons to the first stack and a P-type charge generation layer for supplying holes to the second stack. The N-type charge generation layer may include a metal material as a dopant.

The second stack may be provided on the first stack and configured in a structure in which the hole transporting layer (HTL), a green (G) emitting layer (EML2), and the electron transporting layer (ETL) are stacked sequentially.

The second charge generation layer serves to supply charges to the second stack and the third stack. The second charge generation layer may include an N-type charge generation layer for supplying electrons to the second stack and a P-type charge generation layer for supplying holes to the third stack. The N-type charge generation layer may include a metal material as a dopant.

The third stack may be provided on the second stack and configured in a structure in which the hole transporting layer HTL, a red (R) emitting layer EML3, the electron transporting layer ETL, and the electron injecting layer EIL are stacked sequentially.

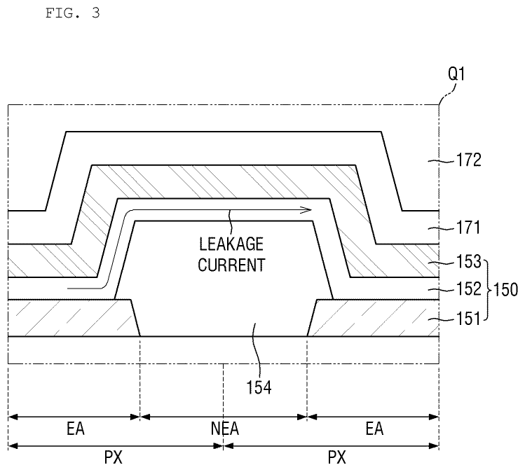

FIG. 3 is an enlarged cross-sectional view of area Q1 in FIG. 2.

Referring to FIGS. 1 to 3, as described above, the organic layer 152 may include a first charge generation layer or a second charge generation layer, and since the organic layer 152 is formed throughout the pixels PX, a lateral leakage current LEAKAGE CURRENT may be generated to an adjacent pixel PX through the first charge generation layer or the second charge generation layer when any one pixel PX emits light. The lateral leakage current generated between adjacent pixels PX may cause the degradation of display quality.

Referring back to FIG. 2, the bank 154 may be disposed to expose the anode electrode 151. The bank 154 may be disposed to cover an edge portion of the anode electrode 151.

The encapsulation part 170 may be disposed on the bank 154 or the light emitting element 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

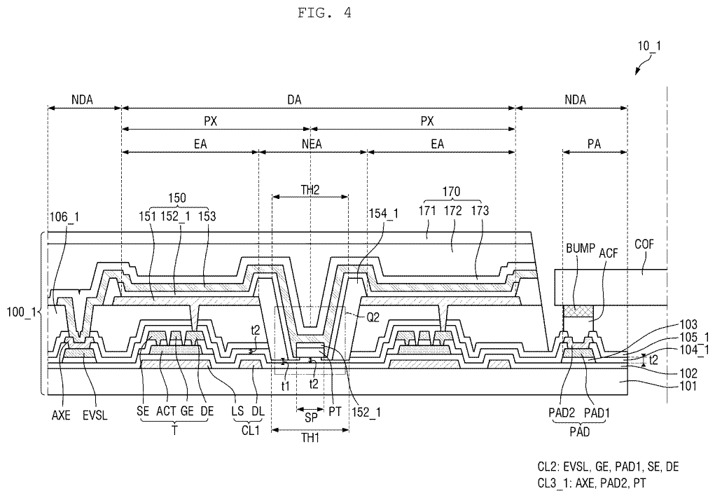

Hereinafter, a second example for solving/minimizing the lateral leakage current of the display device 10 according to the first example will be described. A display device 10_1 according to the second example will be described with reference to FIGS. 4 to 6, and detailed descriptions of the components already described in FIGS. 1 to 3 will be omitted.

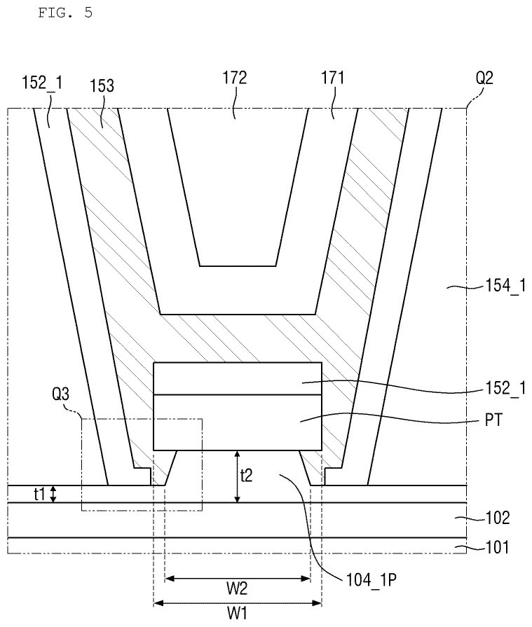

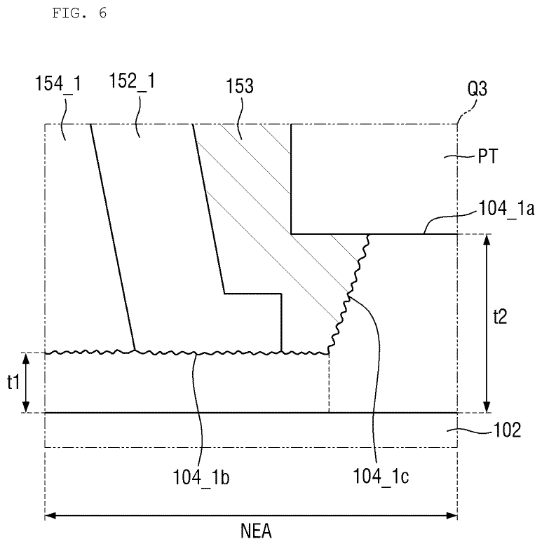

FIG. 4 is a cross-sectional view of a display device according to a second example. FIG. 5 is an enlarged cross-sectional view of area Q2 in FIG. 4. FIG. 6 is an enlarged cross-sectional view of area Q3 in FIG. 5.

Referring to FIGS. 4 to 6, a display panel 100_1 of the display device 10_1 according to the second example differs from the display device 10 according to FIGS. 2 and 3 in that it further includes a protruding pattern (layer) PT.

More specifically, a third conductive layer CL3_1 of the display panel 100_1 may further include the protruding pattern PT. The protruding pattern PT may be disposed at the boundary between adjacent pixels PX, where the boundary is a region or area between adjacent pixels. The protruding pattern or “layer” may define the width of the boundary. The protruding pattern PT may be disposed in the non-emission area NEA.

A first passivation layer 104_1 disposed between the protruding pattern PT and the second conductive layer CL2 may have different thicknesses for each area. For example, the first passivation layer 104_1 may have a protrusion 104_1P that overlaps the protruding pattern PT and has a second thickness t2 greater than a first thickness t1 in the non-emission area NEA and have other areas having the first thickness t1 in the non-emission area NEA. A width W2 of the protrusion 104_1P may be smaller than a width W1 of the protruding pattern PT. The reason why the width of the protrusion 104_1P is smaller than the width of the protruding pattern PT is that the protrusion 104_1P is formed by using the protruding pattern PT as a mask in the non-emission area NEA. Detailed description thereof will be made below in a method of manufacturing the display device 10_1 according to the second example.

In addition, a second passivation layer 105_1 and a planarization layer 106_1 disposed on the protruding pattern PT may each be removed from the non-emission area NEA. Hereinafter, portions removed from the non-emission area NEA of the second passivation layer 105_1 and the planarization layer 106_1 will be referred to as “first through hole TH1.” The first through hole TH1 may fully pass through each of the second passivation layer 105_1 and the planarization layer 106_1 in the thickness direction. Since the second passivation layer 105_1 and the planarization layer 106_1 are removed from the non-emission area NEA, a distance between a surface of the protruding pattern PT and a surface of a bank 154_1 may be increased. This has the advantage of making the patterning process easier. The second passivation layer 105_1 and the planarization layer 106_1 may be removed from the non-emission area NEA to expose the protruding pattern PT.

As described above, since the second passivation layer 105_1 and the planarization layer 106_1 are removed from the non-emission area NEA, the bank 154_1 may be in direct contact with an upper surface of the first passivation layer 104_1 in the non-emission area NEA.

In addition, the bank 154_1 may be removed from the non-emission area NEA like the second passivation layer 105_1 and the planarization layer 106_1. Hereinafter, a portion removed from the non-emission area NEA of the bank 154_1 will be referred to as “second through hole TH2.” The second through hole TH2 may fully pass through the bank 154_1 in the thickness direction.

As shown in FIG. 4, a width of the second through hole TH2 of the bank 154_1 may be smaller than a width of the first through hole TH1 of the second passivation layer 105_1 and the planarization layer 106_1. That is, an inner surface facing the protruding pattern PT of the bank 154_1 may be located to be closer to the protruding pattern PT than inner surfaces facing the protruding pattern PT of the second passivation layer 105_1 and the planarization layer 106_1 are.

The organic layer 152_1 may be disposed on an upper surface of the anode electrode 151, an outer surface of the bank 154_1, an upper surface of the bank 154_1, and an inner surface of the bank 154_1 and may be in direct contact therewith. As described above, since the bank 154_1 is in direct contact with the upper surface of the first passivation layer 104_1 in the non-emission area NEA, a length of the inner surface of the bank 154_1 may be increased in the non-emission area NEA. The length of the inner surface of the bank 154_1 may be greater than a length of an outer side of the bank 154_1. The bank 154_1 may have a regular taper shape. Therefore, the organic layer 152_1 disposed directly on the inner surface of the bank 154_1 may be highly likely separated from the inner surface of the bank 154_1. The increased length/path decreases effect of the leakage current.

In addition, as described above, the protruding pattern PT may have a greater width than the protrusion 104_1P. Side surfaces of the protruding pattern PT may each extend outward more than side surfaces of the protrusion 104_1P. Therefore, the side surfaces of the protrusion 104_1P and the side surfaces of the protruding pattern PT may form a stepped structure. The organic layer 152_1 may extend to the upper surface of the first passivation layer 104_1 through the inner surface of the bank 154_1. However, the organic layer 152_1 may be separated due to the stepped structure formed by the side surfaces of the protrusion 104_1P and the side surfaces of the protruding pattern PT. That is, the organic layer 152_1 may be separated into a portion disposed on the protruding pattern PT and a portion not overlapping the protruding pattern PT. A portion disposed on the protruding pattern PT of the organic layer 152_1 and a portion not overlapping the protruding pattern PT of the organic layer 152_1 may be separated physically.

In addition, as described above, the inner surface facing the protruding pattern PT of the bank 154_1 may be located to be closer to the protruding pattern PT than the inner surfaces facing the protruding pattern PT of the second passivation layer 105_1 and the planarization layer 106_1 are. That is, it is possible to minimize the organic layer 152_1 disposed on the upper surface of the first passivation layer 104_1 exposed by the bank 154_1. When the widths of the first through hole TH1 and the second through hole TH2 are the same, the organic layer 152_1 is in contact with the side surfaces of the bank 154_1, the side surfaces of the planarization layer 106_1, the side surfaces of the second passivation layer 105_1, and the side surfaces of the first passivation layer 104_1 and then extends to the upper surface of the first passivation layer 104_1. In this case, since an area (or a length) of the upper surface of the first passivation layer 104_1 exposed by the bank 154_1 is great, the organic layer 152_1 has the stepped structure formed by the protruding pattern PT and the protrusion 104_1P, but may extend to the upper surface of the protruding pattern PT while being in contact with the side surfaces of the protrusion 104_1P and the side surfaces of the protruding pattern PT. Therefore, when the widths of the first through hole TH1 and the second through hole TH2 are the same, the organic layer 152_1 is not separated by the stepped structure and may extend to the adjacent pixel PX. Again this has the advantage of minimizes the negative effects of any leakage current.

However, in the case of the display device 10_1 according to the second example, the inner surface facing the protruding pattern PT of the bank 154_1 may be located to be closer to the protruding pattern PT than the inner surfaces facing the protruding pattern PT of the second passivation layer 105_1 and the planarization layer 106_1 are, thereby minimizing the organic layer 152_1 disposed on the upper surface of the first passivation layer 104_1 exposed by the bank 154_1. Therefore, it is possible to further increase the possibility that the organic layer 152_1 is separated by the stepped structure.

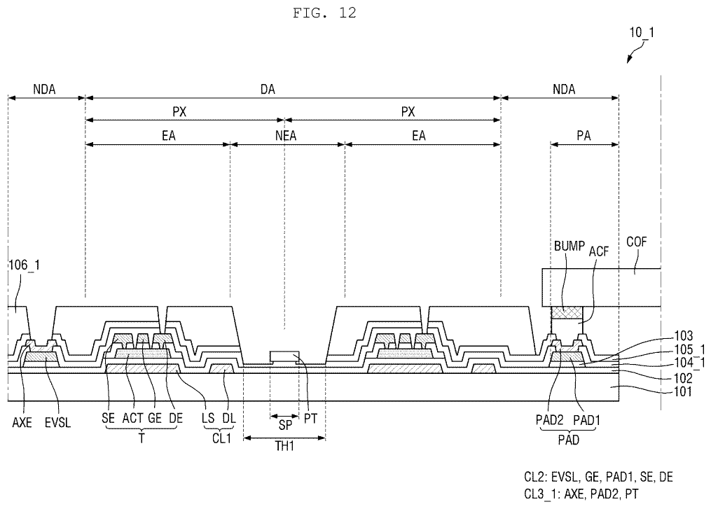

Meanwhile, as shown in FIGS. 5 and 6, in the non-emission area (NEA), the roughness (smooth/flat) of the surface of the first passivation layer 104_1 may be different for each area. As described above, the first passivation layer 104_1 may have a protrusion 104_1P that overlaps the protruding pattern PT and has a second thickness t2 greater than a first thickness t1 in the non-emission area NEA and have other areas having the first thickness t1 in the non-emission area NEA. An upper surface of the protrusion 1041_P will be referred to as “upper surface 104_1a,” and a side surface thereof will be referred to as “side surface 104_1c.” In addition, the upper surface of the first passivation layer 104_1 will be referred to as “upper surface 104_1b.” Comparing the roughness of each surface, the roughness of the top surface 104_1a may be less than the roughness of the side surface 104_1c (eg be of smaller vertical height). The roughness of the upper surface 104_1a may be smaller/less than the roughness of the upper surface 104_1b. When the roughness of the upper surface 104_1a of the protrusion 104_1P having the second thickness t2 is smaller/less than each of the roughness of the upper surface 104_1b of the first passivation layer 104_1 in the non-emission area NEA having the first thickness t1 and the roughness of the side surface 104_1c of the first passivation layer 104_1 connecting the upper surface of the first passivation layer 104_1 in the non-emission area NEA having the first thickness t1 with the upper surface of the protrusion 104_1P, as will be described below in FIG. 12, the side surface 104_1c and the upper surface 104_1b of the first passivation layer 104_1′ exposed by the protruding pattern PT in the process of forming the second passivation layer 105_1 are in contact with etching gas or etchant, resulting in a change in physical properties of the surfaces.

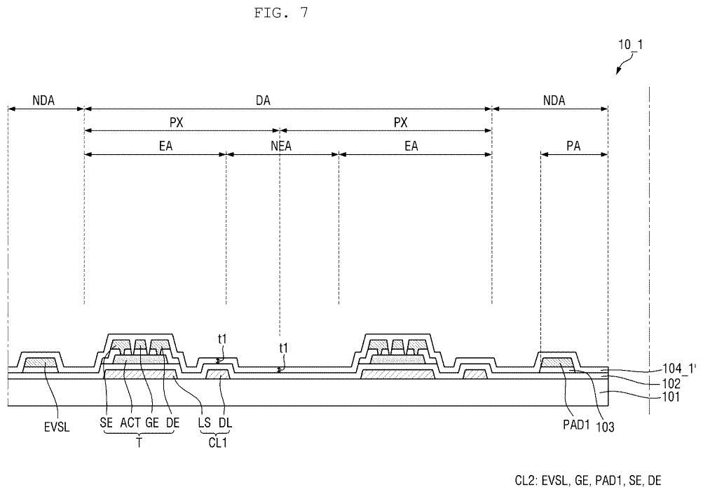

Hereinafter, a method of manufacturing the display device 10_1 according to the second example will be described. The method of manufacturing the display device 10_1 will be described with reference to FIGS. 7 to 17, and detailed descriptions of the components already described in FIGS. 1 to 6 will be omitted.

FIGS. 7 to 17 are cross-sectional views for each process showing a method of manufacturing a display device according to a second example. When the method of manufacturing the display device 10_1 (see FIG. 4) is described with reference to FIGS. 7 to 17, reference may be made to FIGS. 4 to 6 together.

Referring to FIGS. 4 and 7, the first passivation layer 104_1′ is formed on the second conductive layer CL2. The first passivation layer 104_1′ may contain at least one of the exemplified materials of the gate insulating layer 103, but is not limited thereto. The first passivation layer 104_1′ may be formed throughout the display area DA and the non-display area NDA. The first passivation layer 104_1′ may have a uniform thickness t1 for each area. The first passivation layer 104_1′ may partially expose the upper surface of the low potential power line EVSL and the upper surface of the first pad electrode PAD1.

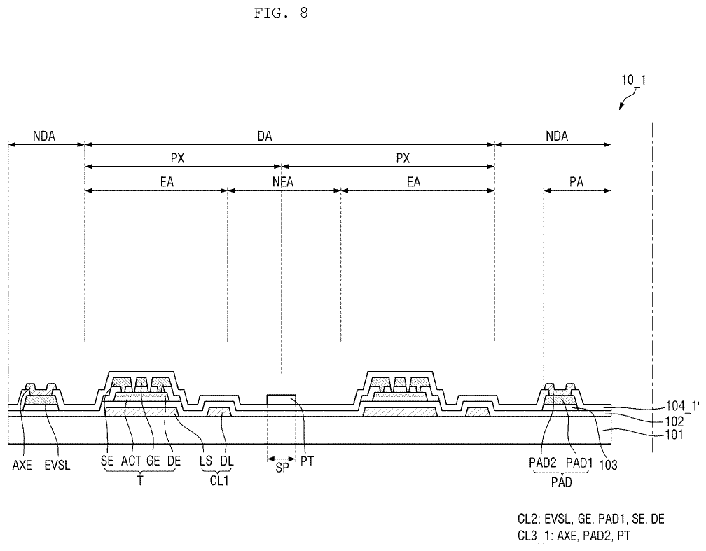

Subsequently, as shown in FIGS. 4 and 8, the third conductive layer CL3_1 is formed on the first passivation layer 104_1′. The third conductive layer CL3_1 may include the auxiliary electrode AXE, the second pad electrode PAD2, and the protruding pattern PT. The auxiliary electrode AXE may be disposed in the non-display area NDA and may overlap the low potential power line EVSL. The second pad electrode PAD2 may be disposed in the pad area PA and may overlap the first pad electrode PAD1. The first passivation layer 104_1′ may partially expose the upper surface of the low potential power line EVSL and the upper surface of the first pad electrode PAD1. The auxiliary electrode AXE and the second pad electrode PAD2 may be in direct contact with the upper surface of the low potential power line EVSL and the upper surface of the first pad electrode PAD1 that are partially exposed. The protruding pattern PT may be disposed at the boundary between adjacent pixels PX or in the non-emission area NEA.

The third conductive layer CL3_1 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but is not limited thereto.

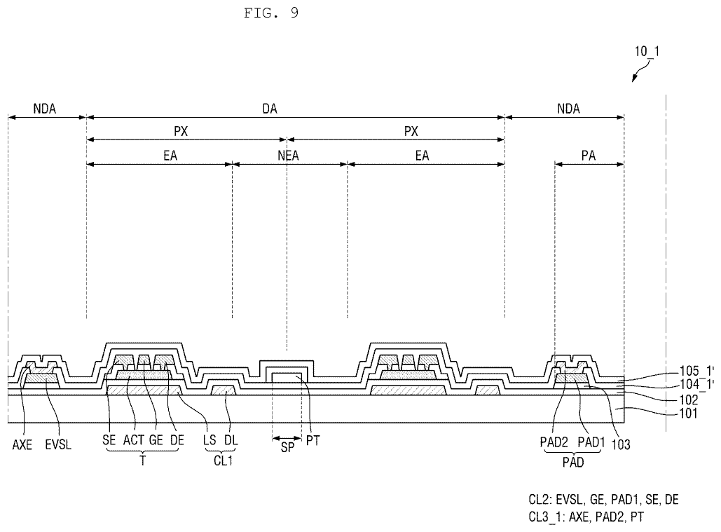

Subsequently, as shown in FIGS. 4 and 9, the second passivation layer 105_1′ is formed on the third conductive layer CL3_1. The second passivation layer 105_1′ may contain at least one of the exemplified materials of the gate insulating layer 103, but is not limited thereto. The second passivation layer 105_1′ may be disposed in the display area DA and the non-display area NDA. The second passivation layer 105_1′ may partially expose the upper surfaces of the auxiliary electrode AXE and the second pad electrode PAD2.

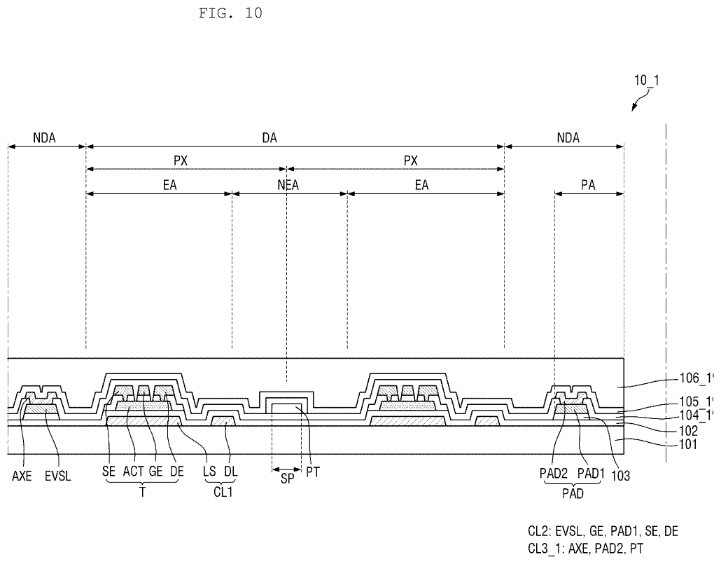

Subsequently, as shown in FIGS. 4 and 10, a planarization layer 106_1′ is formed on the second passivation layer 105_1′. The planarization layer 106_1′ may planarize the upper portion of the thin film transistor T and protect the thin film transistor T. The planarization layer 106_1′ may be made of an organic material. For example, the planarization layer 106_1′ may be made of an organic material includes an acrylic resin, an epoxy resin, a phenolic resin, a polyamide resin, or a polyimide resin, but is not limited thereto. The planarization layer 106_1′ may expose the auxiliary electrode AXE and the pad area PA.

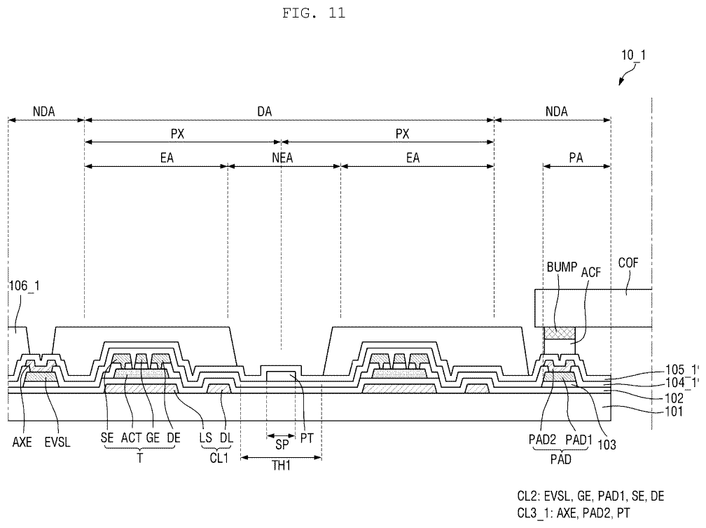

Subsequently, as shown in FIGS. 4 and 11, the first through hole TH1 is formed in the planarization layer 106_1′ of FIG. 10 to form a planarization layer 106′. The planarization layer 106′ may expose the second passivation layer 105′_1 on the auxiliary electrode AXE and the pad area PA. The process of forming the planarization layer 106′ may be an etching process, but is not limited thereto. The etching process may include dry etching or wet etching. Meanwhile, since the first through hole TH1 of the planarization layer 106′ exposes the second passivation layer 105′_1 on the protruding pattern PT, it is preferable that a selectivity ratio of the etching gas or etchant used to etch the planarization layer 106′ between/to the planarization layer 106′ and the second passivation layer 105′_1 is high. For example, an etch rate of the etch gas or etchant used to etch the planarization layer 106′ may be greater than an etch rate of the second passivation layer 105′_1.

Subsequently, as shown in FIGS. 4 and 12, the first through hole TH1 is formed in the second passivation layer 105_1′ of FIG. 11 to form a second passivation layer 105_1′. The second passivation layer 105_1′ may expose the upper surfaces of the auxiliary electrode AXE and the upper surface of the second pad electrode PAD2.

The process of forming the planarization layer 105′ may be an etching process, but is not limited thereto. The etching process may include dry etching or wet etching. Meanwhile, as described above, in the process of forming the second passivation layer 105′, the first passivation layer 104′_1 (see FIG. 11) overlapping the protruding pattern PT may not be etched underneath/by the protruding pattern PT. Therefore, in the process of forming the second passivation layer 105′, the protrusion 104_1P having the first thickness t1 of the first passivation layer 104′ in the non-emission area NEA and the area having the second thickness t2 near the protrusion 104_1P may be formed.

Meanwhile, in the process of forming the second passivation layer 105′, the protruding pattern PT is not substantially etched, but the first passivation layer 104′_1 (see FIG. 11) may be etched partially. That is, the selectivity ratio of the etching gas or etchant used to etch the second passivation layer 105′ between the second passivation layer 105′ and the first passivation layer 104′ 1 (see FIG. 1) may be smaller than the selectivity ratio of the etching gas or etchant between the second passivation layer 105′ and the protruding pattern PT. In addition, the etch rate of the etching gas or etchant used to etch the second passivation layer 105′ to the second passivation layer 105′ may be greater than the etch rate of the etching gas or etchant to the first passivation layer 104′_1 (see FIG. 11) and the protruding pattern PT, and the etch rate of the etching gas or etchant to the first passivation layer 104′_1 (see FIG. 11) may be greater than the etch rate of the etching gas or etchant to the protruding pattern PT.

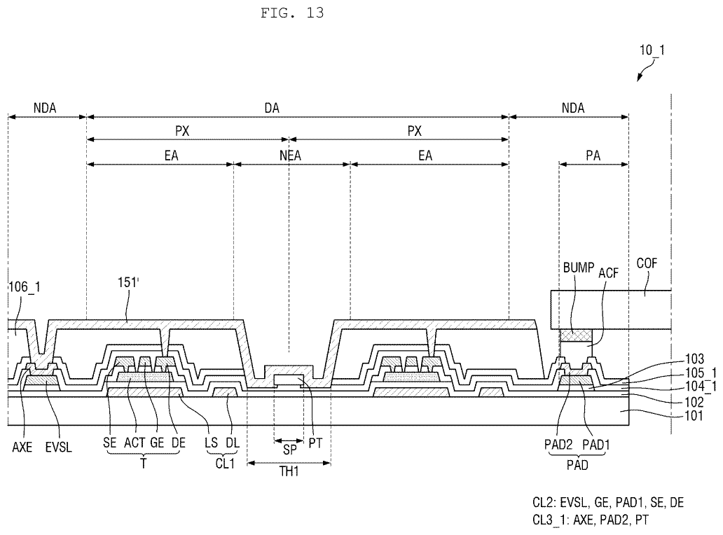

Subsequently, as shown in FIGS. 4 and 13, an anode electrode layer 151′ is formed on the planarization layer 106′. The anode electrode layer 151′ is disposed throughout the display area DA and the non-display area NDA. The anode electrode layer 151′ may contain a reflective material that reflects light, but is not limited thereto. The anode electrode layer 151′ may include a stacking structure (Ti/Al/Ti) of aluminum (Al) and titanium (Ti), a stacking structure (ITO/Al/ITO) of aluminum (Al) and ITO, and a metal material having high reflectance such as an APC alloy and may be formed of a single layer or multiple layers, but is not limited thereto.

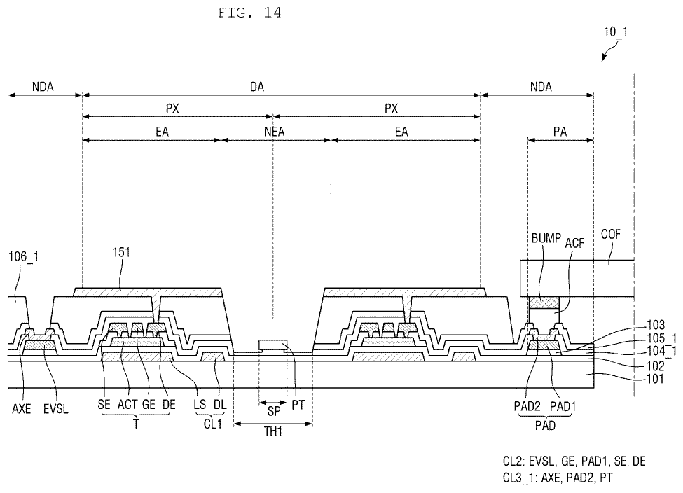

Subsequently, as shown in FIGS. 4 and 14, the anode electrode layer 151′ (see FIG. 13) is etched to form the anode electrode 151. The process of forming the anode electrode 151 may be an etching process, but is not limited thereto. The etching process may include dry etching or wet etching. Meanwhile, in the process of forming the anode electrode 151, the protruding pattern PT may not be substantially etched. Therefore, it is preferable that the selectivity ratio of the etching gas or etchant used to etch the anode electrode layer 151′ (see FIG. 13) between the anode electrode layer 151′ and the protruding pattern PT is high. For example, the etching rate for the anode electrode layer 151′ (see FIG. 13) of the etching gas or etchant used to etch the anode electrode layer 151′ (see FIG. 13) may be greater than the etching rate of the etching gas or etchant to the protruding pattern PT.

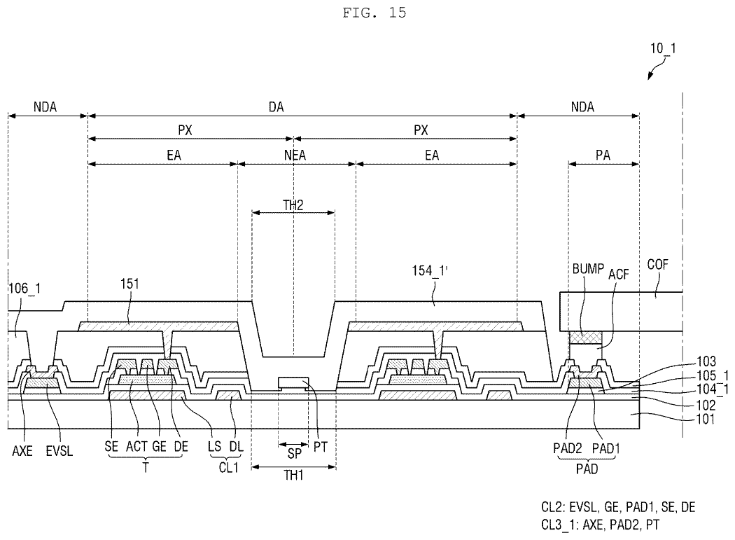

Subsequently, as shown in FIGS. 4 and 15, a bank layer 154_1′ is formed on the anode electrode 151.

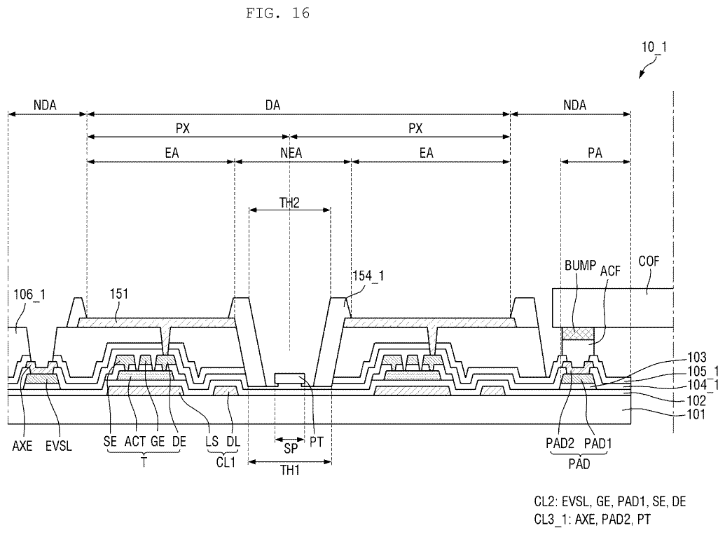

Subsequently, as shown in FIGS. 4 and 16, the bank layer 154_1′ (see FIG. 15) is etched to form the bank 154_1. The bank 154_1 may expose the pad area PA, and the second through hole TH2 may be formed in the non-emission area NEA to expose the protruding pattern PT. The width of the second through hole TH2 of the bank 154_1 may be smaller than the width of the first through hole TH1 of the second passivation layer 105_1 and the planarization layer 106_1. That is, an inner surface facing the protruding pattern PT of the bank 154_1 may be located to be closer to the protruding pattern PT than inner surfaces facing the protruding pattern PT of the second passivation layer 105_1 and the planarization layer 106_1 are. Since the second passivation layer 105_1 and the planarization layer 106_1 are removed from the non-emission area NEA, the bank 154_1 may be in direct contact with the upper surface of the first passivation layer 104_1 in the non-emission area NEA.

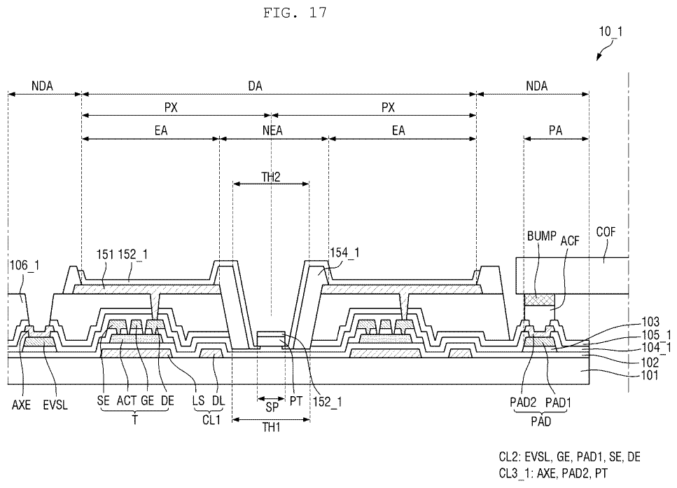

Subsequently, as shown in FIGS. 4 and 17, the organic layer 152_1 is formed on the bank 154_1, the anode electrode 151, and the first passivation layer 104_1. The organic layer 152_1 may include the first stack, the second stack, and the first charge generation layer that are provided on the anode electrode 151, or include the first stack, the second stack, the third stack, the first charge generation layer between the first stack and the second stack, and the second charge generation layer between the second stack and the third stack, which are provided on the anode electrode.

As described above in FIGS. 4 and 5, the organic layer 152_1 may be disposed on the upper surface of the anode electrode 151, the outer surface of the bank 154_1, the upper surface of the bank 154_1, and the inner surface of the bank 154_1 and may be in direct contact therewith. Since the bank 154_1 is in direct contact with the upper surface of the first passivation layer 104_1 in the non-emission area NEA, the length of the inner surface of the bank 154_1 may be increased in the non-emission area NEA. The length of the inner surface of the bank 154_1 may be greater than a length of an outer side of the bank 154_1. The bank 154_1 may have a regular taper shape. Therefore, the organic layer 152_1 disposed directly on the inner surface of the bank 154_1 may be highly likely separated from the inner surface of the bank 154_1.

In addition, as described above, the protruding pattern PT may have a greater width than the protrusion 104_1P. The side surfaces of the protruding pattern PT may each extend outward more than side surfaces of the protrusion 104_1P. Therefore, the side surfaces of the protrusion 104_1P and the side surfaces of the protruding pattern PT may form a stepped structure. The organic layer 152_1 may extend to the upper surface of the first passivation layer 104_1 through the inner surface of the bank 154_1. However, the organic layer 152_1 may be separated due to the stepped structure formed by the side surfaces of the protrusion 104_1P and the side surfaces of the protruding pattern PT. That is, the organic layer 152_1 may be separated into a portion disposed on the protruding pattern PT and a portion not overlapping the protruding pattern PT. A portion disposed on the protruding pattern PT of the organic layer 152_1 and a portion not overlapping the protruding pattern PT of the organic layer 152_1 may be separated physically.

In addition, as described above, the inner surface facing the protruding pattern PT of the bank 154_1 may be located to be closer to the protruding pattern PT than the inner surfaces facing the protruding pattern PT of the second passivation layer 105_1 and the planarization layer 106_1 are. That is, it is possible to minimize the organic layer 152_1 disposed on the upper surface of the first passivation layer 104_1 exposed by the bank 154_1. When the widths of the first through hole TH1 and the second through hole TH2 are the same, the organic layer 152_1 is in contact with the side surfaces of the bank 154_1, the side surfaces of the planarization layer 106_1, the side surfaces of the second passivation layer 105_1, and the side surfaces of the first passivation layer 104_1 and then extends to the upper surface of the first passivation layer 104_1. In this case, since an area (or a length) of the upper surface of the first passivation layer 104_1 exposed by the bank 154_1 is great, the organic layer 152_1 has the stepped structure formed by the protruding pattern PT and the protrusion 104_1P, but may extend to the upper surface of the protruding pattern PT while being in contact with the side surfaces of the protrusion 104_1P and the side surfaces of the protruding pattern PT. Therefore, when the widths of the first through hole TH1 and the second through hole TH2 are the same, the organic layer 152_1 is not separated by the stepped structure and may extend to the adjacent pixel PX.

However, in the case of the display device 10_1 according to the second example, the inner surface facing the protruding pattern PT of the bank 154_1 may be located to be closer to the protruding pattern PT than the inner surfaces facing the protruding pattern PT of the second passivation layer 105_1 and the planarization layer 106_1 are, thereby minimizing the organic layer 152_1 disposed on the upper surface of the first passivation layer 104_1 exposed by the bank 154_1. Therefore, it is possible to further increase the possibility that the organic layer 152_1 is separated by the stepped structure.

The display device according to various examples of the present specification may be described as follows.

A display device includes a substrate including a display area including a plurality of pixels, and a non-display area surrounding the display area, a protruding pattern disposed on the substrate and located at a boundary of adjacent pixels, an anode electrode disposed on each of the pixels on the substrate, a bank disposed on the anode electrode and exposing the protruding pattern, and an organic layer disposed on the anode electrode and the bank, in which the organic layer is separated at the boundary of the pixels.

The bank may partially expose the upper surface of the anode electrode and include a through hole at the boundary of the pixels, and the through hole may overlap the protruding pattern.

The organic layer may cover an upper and side surfaces of the bank and may be disconnected (not covering/separated from) on an end portion of the protruding pattern.

The organic layer may be further disposed on an upper surface of the protruding pattern, and the organic layer disposed on the upper surface of the protruding pattern and the organic layer disconnected on the end portion of the protruding pattern may be separated.

The display device may further include a first passivation layer between the substrate and the protruding pattern, in which at the boundary of the pixels, a second thickness of the first passivation layer overlapping the protruding pattern may be greater than a first thickness of the first passivation layer not overlapping the protruding pattern.

A width of the first passivation layer having the second thickness may be smaller than a width of the protruding pattern.

The surface roughness of the first passivation layer having the first thickness may be greater than the surface roughness of the first passivation layer having the second thickness.

The display device may further include a second passivation layer disposed between the protruding pattern and the anode electrode, in which the second passivation layer may not be disposed at the boundary of the pixels.

The display device may further include a planarization layer between the second passivation layer and the anode electrode, in which the planarization layer may not be disposed at the boundary of the pixels.

The pixel may include a white pixel.

The display device may further include a cathode electrode on the organic layer, in which the cathode electrode may be in direct contact with a side surface of the protruding pattern.

A display device includes a substrate including a display area including a plurality of pixels, and a pad area near the display area, a first conductive layer including a data line and a light blocking layer on the substrate, a semiconductor layer overlapping the light blocking layer on the first conductive layer, a gate insulating layer on the semiconductor layer, a second conductive layer including a first pad electrode disposed in the pad region on the gate insulating layer, a gate electrode overlapping a channel area of the semiconductor layer, a source electrode connected to a source area of the semiconductor layer, and a drain electrode connected to a drain area of the semiconductor layer, a first passivation layer disposed on the second conductive layer, and a third conductive layer disposed on the first passivation layer and including a second pad electrode disposed on the first pad electrode in the pad area and a protruding pattern located at a boundary of the pixels.

The display device may further include an anode electrode disposed on the third conductive layer and in each of the pixels, and a bank disposed on the anode electrode and exposing the protruding pattern.

The display device may further include an organic layer disposed on the anode electrode and the bank, in which the organic layer may be separated at the boundary of the pixels.

The bank may partially expose the upper surface of the anode electrode and include a through hole at the boundary of the pixels, and the through hole may overlap the protruding pattern.

The organic layer may cover an upper and side surfaces of the bank and may be disconnected (not cover) on an end portion of the protruding pattern.

The organic layer may be further disposed on an upper surface of the protruding pattern, and the organic layer disposed on the upper surface of the protruding pattern and the organic layer disconnected on the end portion of the protruding pattern may be separated.

The display device may further include a first passivation layer between the substrate and the protruding pattern, in which at the boundary of the pixels, a second thickness of the first passivation layer overlapping the protruding pattern may be greater than a first thickness of the first passivation layer not overlapping the protruding pattern.

A width of the first passivation layer having the second thickness may be smaller than a width of the protruding pattern.

The surface roughness of the first passivation layer having the first thickness may be greater than the surface roughness of the first passivation layer having the second thickness. Further examples are set out in the clauses below:

A display device may comprise a substrate including a display area including a plurality of pixels, and a non-display area surrounding the display area; a protruding pattern disposed on the substrate and located at a boundary of adjacent pixels; an anode electrode disposed on each of the pixels on the substrate; a bank disposed on the anode electrode and exposing the protruding pattern; and an organic layer disposed on the anode electrode and the bank, wherein the organic layer is separated by the protruding pattern at the boundary of the pixels.

A display device may comprises a substrate including a display area including a plurality of pixels, and a non-display area surrounding the display area; a protruding pattern disposed on the substrate and located at a boundary of adjacent pixels; an anode electrode disposed on each of the pixels on the substrate; a bank disposed on the anode electrode and exposing the protruding pattern; and an organic layer disposed on the anode electrode and the bank, wherein the organic layer is discontinuous at the boundary of the pixels.

The organic layer is separated by the protruding pattern at the boundary of the pixels.

The bank partially exposes an upper surface of the anode electrode and includes a through hole at the boundary of the pixels, and the through hole overlaps the protruding pattern.

The organic layer covers an upper and side surfaces of the bank and is does not cover end portion of the protruding pattern.

The organic layer is further disposed on an upper surface of the protruding pattern, and the organic layer disposed on the upper surface of the protruding pattern and the organic layer not disposed on the end portion of the protruding pattern.

The display device further comprises a first passivation layer between the substrate and the protruding pattern, wherein at the boundary of the pixels, a second thickness of the first passivation layer overlapping the protruding pattern is greater than a first thickness of the first passivation layer not overlapping the protruding pattern.

A width of the first passivation layer having the second thickness is smaller than a width of the protruding pattern.

The surface roughness of an upper surface of the first passivation layer having the first thickness is greater than the surface roughness of an upper surface of the first passivation layer having the second thickness.

The display device may further comprise a second passivation layer disposed between the protruding pattern and the anode electrode, wherein the second passivation layer is not disposed at the boundary of the pixels; and a planarization layer between the second passivation layer and the anode electrode, wherein the planarization layer is not disposed at the boundary of the pixels.

The pixel includes an emission area, and a non-emission area, and the protruding pattern is disposed in the non-emission area.

The display device may further comprise a cathode electrode on the organic layer, wherein the cathode electrode is in direct contact with a side surface of the protruding pattern.

A portion of the organic layer is disposed on the protruding pattern, and the remaining portion of the organic layer not disposed on the protruding pattern is separated physically from the portion disposed on the protruding pattern.

A display device may comprise a substrate including a display area including a plurality of pixels, and a pad area near the display area; a first conductive layer including a data line and a light blocking layer on the substrate; a semiconductor layer overlapping the light blocking layer on the first conductive layer; a gate insulating layer on the semiconductor layer; a second conductive layer including a first pad electrode disposed in the pad region on the gate insulating layer, a gate electrode overlapping a channel area of the semiconductor layer, a source electrode connected to a source area of the semiconductor layer, and a drain electrode connected to a drain area of the semiconductor layer; a first passivation layer disposed on the second conductive layer; a third conductive layer disposed on the first passivation layer and including a second pad electrode disposed on the first pad electrode in the pad area and a protruding pattern located at a boundary of the pixels; and an organic layer, wherein the organic layer is discontinuous at the boundary of the pixels by the protruding pattern.

The organic layer is separated by the protruding pattern at the boundary of the pixels.

The display device may further comprise an anode electrode disposed on the third conductive layer and in each of the pixels; and a bank disposed on the anode electrode and exposing the protruding pattern.

The organic layer is disposed on the anode electrode and the bank.

The bank partially exposes an upper surface of the anode electrode and includes a through hole at the boundary of the pixels, and the through hole overlaps the protruding pattern.

The organic layer covers an upper and side surfaces of the bank and does not cover on an end portion of the protruding pattern.

The organic layer is further disposed on an upper surface of the protruding pattern, and the organic layer disposed on the upper surface of the protruding pattern and the organic layer is not disposed on the end portion of the protruding pattern are separated.

The display device may further comprise a first passivation layer between the substrate and the protruding pattern, wherein at the boundary of the pixels, a second thickness of the first passivation layer overlapping the protruding pattern is greater than a first thickness of the first passivation layer not overlapping the protruding pattern.

A width of the first passivation layer having the second thickness is smaller than a width of the protruding pattern.

The surface roughness of an upper surface of the first passivation layer having the first thickness is greater than the surface roughness of an upper surface of the first passivation layer having the second thickness.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

### DESCRIPTION OF REFERENCE NUMERALS

10, 10_1: display device
100, 100_1: display panel
CL1: first conductive layer
CL2: second conductive layer
CL3, CL3_1: third conductive layer
PT: protruding pattern

What is claimed is:

1. A display device, comprising:
a substrate including a display area including a plurality of pixels, and a non-display area surrounding the display area;
a protruding pattern disposed on the substrate and located at a boundary of adjacent pixels;
an anode electrode disposed on each of the pixels on the substrate;
a bank disposed on the anode electrode and exposing the protruding pattern; and
an organic layer disposed on the anode electrode and the bank,
wherein the organic layer is discontinuous at the boundary of the pixels.

2. The display device of claim 1, wherein the organic layer is separated by the protruding pattern at the boundary of the pixels.

3. The display device of claim 1, wherein the bank partially exposes an upper surface of the anode electrode and includes a through hole at the boundary of the pixels, and the through hole overlaps the protruding pattern.

4. The display device of claim 3, wherein the organic layer covers an upper and side surfaces of the bank and is does not cover end portion of the protruding pattern.

5. The display device of claim 1, wherein the organic layer is further disposed on an upper surface of the protruding pattern, and the organic layer disposed on the upper surface of the protruding pattern and the organic layer not disposed on the end portion of the protruding pattern.

6. The display device of claim 3, further comprising a first passivation layer between the substrate and the protruding pattern, wherein at the boundary of the pixels, a second thickness of the first passivation layer overlapping the protruding pattern is greater than a first thickness of the first passivation layer not overlapping the protruding pattern.

7. The display device of claim 6, wherein a width of the first passivation layer having the second thickness is smaller than a width of the protruding pattern.

8. The display device of claim 6, wherein the surface roughness of an upper surface of the first passivation layer having the first thickness is greater than the surface roughness of an upper surface of the first passivation layer having the second thickness.

9. The display device of claim 7, further comprising: a second passivation layer disposed between the protruding pattern and the anode electrode, wherein the second passivation layer is not disposed at the boundary of the pixels; and
a planarization layer between the second passivation layer and the anode electrode, wherein the planarization layer is not disposed at the boundary of the pixels.

10. The display device of claim 1, wherein the pixel includes an emission area, and a non-emission area, and the protruding pattern is disposed in the non-emission area.

11. The display device of claim 1, further comprising a cathode electrode on the organic layer, wherein the cathode electrode is in direct contact with a side surface of the protruding pattern.

12. The display device of claim 1, wherein a portion of the organic layer is disposed on the protruding pattern, and the remaining portion of the organic layer not disposed on the protruding pattern is separated physically from the portion disposed on the protruding pattern.

13. A display device, comprising:
a substrate including a display area including a plurality of pixels, and a pad area near the display area;
a first conductive layer including a data line and a light blocking layer on the substrate;
a semiconductor layer overlapping the light blocking layer on the first conductive layer;
a gate insulating layer on the semiconductor layer;
a second conductive layer including a first pad electrode disposed in the pad region on the gate insulating layer, a gate electrode overlapping a channel area of the semiconductor layer, a source electrode connected to a source area of the semiconductor layer, and a drain electrode connected to a drain area of the semiconductor layer;
a first passivation layer disposed on the second conductive layer;
a third conductive layer disposed on the first passivation layer and including a second pad electrode disposed on the first pad electrode in the pad area and a protruding pattern located at a boundary of the pixels; and
an organic layer, wherein the organic layer is discontinuous at the boundary of the pixels by the protruding pattern.

14. The display device of claim 13, wherein the organic layer is separated by the protruding pattern at the boundary of the pixels.

15. The display device of claim 13, further comprising an anode electrode disposed on the third conductive layer and in each of the pixels; and a bank disposed on the anode electrode and exposing the protruding pattern.

16. The display device of claim 13, wherein the organic layer is disposed on the anode electrode and the bank.

17. The display device of claim 13, wherein the bank partially exposes an upper surface of the anode electrode and includes a through hole at the boundary of the pixels, and the through hole overlaps the protruding pattern.

18. The display device of claim 16, wherein the organic layer covers an upper and side surfaces of the bank and does not cover on an end portion of the protruding pattern.

19. The display device of claim 13, wherein the organic layer is further disposed on an upper surface of the protruding pattern, and the organic layer disposed on the upper surface of the protruding pattern and the organic layer is not disposed on the end portion of the protruding pattern are separated.

20. The display device of claim 19, further comprising a first passivation layer between the substrate and the protruding pattern, wherein at the boundary of the pixels, a second thickness of the first passivation layer overlapping the protruding pattern is greater than a first thickness of the first passivation layer not overlapping the protruding pattern.

21. The display device of claim 20, wherein a width of the first passivation layer having the second thickness is smaller than a width of the protruding pattern.

22. The display device of claim 20, wherein the surface roughness of an upper surface of the first passivation layer having the first thickness is greater than the surface roughness of an upper surface of the first passivation layer having the second thickness.
